(19) United States
(12) Patent Application Publication
(10) Pub. No.: US 2012/0162543 A1
(43) Pub. Date: Jun. 28, 2012

(54) TELEVISION AND ELECTRONIC DEVICE

(75) Inventors: Takayoshi Tomioka, Fukaya-shi (JP); Teruyuki Kamizuru, Fukaya-shi (JP)

(73) Assignee: KABUSHIKI KAISHA TOSHIBA, Tokyo (JP)

(21) Appl. No.: 13/329,181

(22) Filed: Dec. 16, 2011

(30) Foreign Application Priority Data
Dec. 27, 2010 (JP) 2010-291253

(51) Int. Cl. H04N 5/66; H05K 7/00

(52) U.S. Cl. 348/739; 361/679.01; 348/E05.133

(57) ABSTRACT

According to one embodiment, a television includes a display apparatus, a casing, a tuner and a support section. The display apparatus includes a display screen. The casing exhibits a static inhibiting effect. The casing houses the display apparatus and includes a first face section provided with an opening through which the display screen is exposed and a second face section positioned at the opposite side of the casing to the first face section. The tuner is housed in the casing. The support section exhibits a static inhibiting effect and supports the casing.

### CROSS REFERENCE TO RELATED APPLICATION(S)

This application is based upon and claims the benefit of priority from Japanese Patent Application No. 2010-291253 filed on Dec. 27, 2010, the entire contents of which are incorporated herein by reference.

### BACKGROUND OF THE INVENTION

1. Field of the Invention

Embodiments described herein relate generally to a television and an electronic device.

2. Description of the Related Art

Electronic devices with static inhibiting structures are known.

### BRIEF DESCRIPTION OF THE DRAWINGS

A general configuration that implements the various features of the invention will be described with reference to the drawings. The drawings and the associated descriptions are provided to illustrate embodiments of the invention and not to limit the scope of the invention.

FIG. 1 shows a display apparatus serving as an electronic device as viewed from the display screen side according to an exemplary embodiment;

FIG. 2 shows the display apparatus serving as the electronic device as viewed from the opposite side to the display screen side according to the exemplary embodiment;

FIG. 3 shows the display apparatus serving as the electronic device as viewed from the side according to the exemplary embodiment;

FIG. 4 shows a configuration of a casing during molding according to the exemplary embodiment;

FIG. 5 shows a front cover as viewed from the inside of the casing according to the exemplary embodiment;

FIG. 6 shows a partial enlargement of a state of the front cover as viewed from the inside of the casing;

FIG. 7 shows an enlarged cross-section of a portion of the front cover as viewed from the casing inside according to the exemplary embodiment;

FIG. 8 shows a schematic diagram of a molten material flow in the exemplary embodiment;

FIG. 9 is a first modified example of projection portions of the exemplary embodiment;

FIG. 10 is a second modified example of the projection portions of the exemplary embodiment;

FIG. 11 is a third modified example of the projection portions of the exemplary embodiment;

FIG. 12 is a fourth modified example of the projection portions of the exemplary embodiment; and

FIG. 13 is a fifth modified example of the projection portions of the exemplary embodiment.

### DETAILED DESCRIPTION

In general, according to one embodiment, a television includes a display apparatus, a casing, a tuner and a support section. The display apparatus includes a display screen. The casing exhibits a static inhibiting effect. The casing houses the display apparatus and includes a first face section provided with an opening through which the display screen is exposed and a second face section positioned at the opposite side of the casing to the first face section. The tuner is housed in the casing. The support section exhibits a static inhibiting effect and supports the casing.

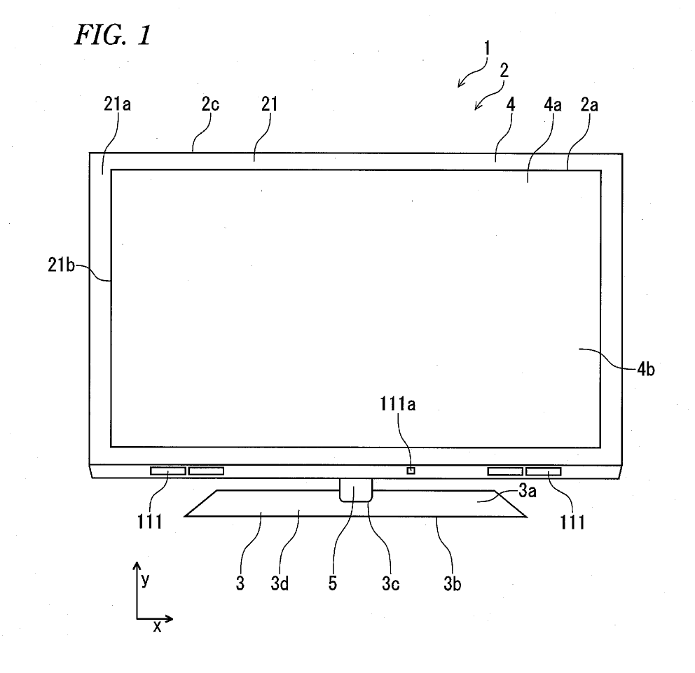

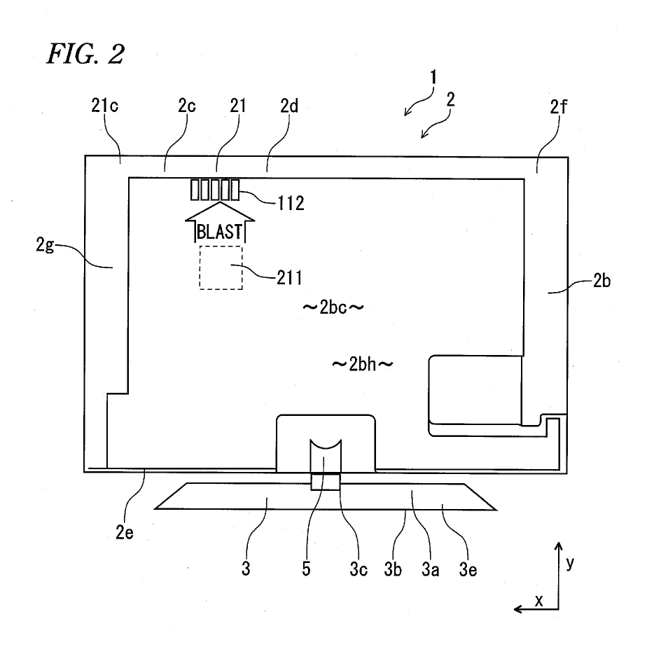

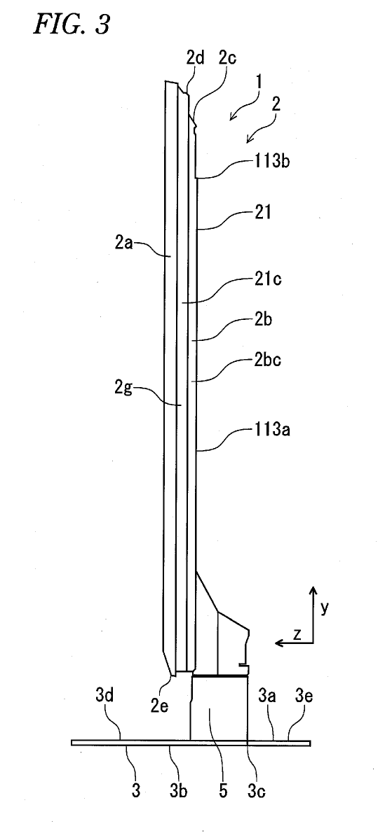

Detailed explanation follows regarding exemplary embodiments, with reference to the drawings. For ease of explanation directions are defined below. FIG. 1 shows a display apparatus (television, broadcast reception apparatus, electronic device) 1 as viewed from the display screen side (front face, head-on) of a display section (display, display panel) 2. FIG. 2 shows the display apparatus serving as the electronic device of the present exemplary embodiment as viewed from the opposite side to the display screen side (from the back face, rear face). FIG. 3 shows the display apparatus serving as the electronic device of the present exemplary embodiment as viewed from the side.

As an example, the right hand side direction when the display section 2 is viewed face on (in front view) (the left hand side direction when viewed from the rear (in back view)) is designated the direction X, the up direction is designated the direction Y, and the depth direction (front direction) is designated the direction Z. Arrows illustrate these directions in each of the drawings with respect to the assembled state of the display apparatus 1.

As shown in FIG. 1, the display apparatus 1 according to the present exemplary embodiment includes: a base section (base, plate section, support section, support member) 3 that is installed on a desk, for example; the display section 2 housing a display unit 4, such as a Liquid Crystal Display (LCD); and a connection section 5 (coupling section, support section, neck section, support member) connected to the display section 2 and supported by the base section 3.

As shown in FIG. 1, the base section 3 is formed with a flat face that contacts the top of a desk for example (a face in the same plane as the desk top), adopting a flat shape comparatively thin in the display apparatus 1 vertical direction. The base section 3 is provided with a top face 3a, a bottom face 3b, a portion 3c connected to the connection section 5, a first face portion 3d located on the display screen side, and a second face portion 3e located on the opposite direction to the display screen side.

As shown in FIG. 1 and FIG. 2, the display section 2 is configured by a flat substantially rectangular box shape including a front face (display face, first face, front face) 2a, a back face (non-display face, second face, back face) 2b positioned on the opposite side to that of the front face 2a, a peripheral face (side face, edge of covering portion, end of covering portion) 2c spanning between the front face 2a and the back face 2b. The display section 2 exhibits a rectangular shaped external appearance, thin in the front-rear direction and longer in the width direction when viewed from the front. The peripheral face 2c has face sections split broadly into four sections, a top face (side face, top wall) 2d, bottom face (side face, lower wall, bottom wall) 2e, right face (side face, side wall) 2f, and left face (side face, side wall) 2g. The back face 2b includes a central region 2bc and a peripheral region 2bh. The central region 2bc is a region disposed at a position in the vicinity of and facing the center of a display screen. The peripheral region 2bh is a region along (overlapping with) the peripheral face 2c surrounding the central region 2bc.

A casing 21 of the display section 2 includes a front mask (front face of the casing 21, display face of the casing 21, first face of the casing 21, front-on face of the casing 21, mask portion, front cover, cover portion) 21 a and a back cover (back face of the casing 21, non-display face of the casing 21, second face of the casing 21, rear face of the casing 21, back cover, cover portion) 21c. A rectangular shaped opening 21 b is provided in the front mask 21 a as a portion of the casing 21 covering a peripheral portion of a front face 4a of the display unit 4. The front face 4a of the display unit 4 is exposed through the opening 21b. In the present exemplary embodiment, the portion of the front face 4a of the display unit 4 exposed from the opening 21b configures a display screen 4b. The display screen 4b is disposed upright (perpendicular or substantially perpendicular/orthogonal or substantially orthogonal) to the installation face of the support portion, as shown in FIG. 1 and FIG. 2.

As shown in FIG. 3, these faces of the casing 21 widen on progression from the back face 2b towards the front face 2a. Namely, the back face 2b has a smaller surface area than the front face 2a, and is positioned so as to fall within the outer periphery of the front face 2a when viewed straight on along the front-rear direction of the display screen. All of the top face 2d, the bottom face 2e, the right face 2f and the left face 2g are of a sloping shape inclined with respect to the front face 2a (the back face 2b).

As shown in FIG. 3, the top face 2d and the bottom face 2e are formed so as to slope towards the back face of the display apparatus 1. Such a configuration achieves the effect of making the external appearance of the electronic device appear thinner. Due to configuration with this shape the electronic components, such as substrates, are housed at the back face of the display section 2 positioned separated from the display section 2 in the electronic device of the present exemplary embodiment.

As shown in FIG. 3, the top face 2d and the bottom face 2e are provided with steps or slop portions (sloped faces, inclined portions) such that the casing 21 is thickest at the central portion and becomes thinner on progression towards the edge portions of the casing 21. Such a configuration achieves an effect similar to the slope on the top face 2d in making the external appearance of the electronic device appear thinner.

In addition to the display unit 4, a substrate 40 mounted with electronic components, such as a Central Processing Unit (CPU) and other electronic components (not shown in the drawings), are also internally housed in the casing 21 of the display section 2. The display unit 4 acquires a video signal from a video signal processing circuit included in a control circuit configured with electronic components mounted on a board (not shown in the drawings), and displays a video, such as a still picture or motion picture, on the display screen 4b. When the display apparatus 1 is configured by a television set, the control circuit of the display apparatus 1 includes, in addition to the video signal processing circuit, for example, a tuner module and a High Definition Multimedia Interface (HDMI) signal processing module, an Audio Video (AV) input terminal, a remote controller signal receiver, a controller, a selector, an on-screen display interface, a storage module (for example, Read Only Memory (ROM), Random Access Memory (RAM) or a Hard Disk Drive (HDD)) and an audio signal processing circuit. The board is housed in the casing 21 towards the rear (at the back face side) of the display unit 4. When the display apparatus 1 is configured by a computer, the control circuit of the display apparatus 1 includes, for example, a controller (for example a CPU) and a storage module (for example, Read Only Memory (ROM), Random Access Memory (RAM) or a Hard Disk Drive (HDD)), a display driver, and a communication interface. The display apparatus 1 also includes an amplifier (not shown in the drawings) and speakers 111 for audio output.

As shown in FIG. 1 to FIG. 3, a connection portion 5 is connected to the casing 21 at a position at the center (central portion) in the length direction of the back face 2b, namely positioned such that the casing 21 is supported in the left-right direction with its weight symmetrically or substantially symmetrically supported. For example, in an electronic device such as a television, not only is a structural design required to give stability at a point of connection to the connection portion 5 so as to support without tipping over in the front-rear direction, but there is also a requirement to stabilize against swaying and tipping over in the left-right direction. By employing the configuration of the present exemplary embodiment, the display apparatus 1 exhibits resistance to swaying with respect to the length direction (left-right direction) of the casing 21.

In the display apparatus 1 of the present exemplary embodiment the casing 21, the base section 3 and the connection portion 5 are subjected to anti-static treatment. Explanation follows regarding the anti-static treated display apparatus 1.

The display apparatus 1 of the present exemplary embodiment is configured from a synthetic resin material (plastic) into which is mixed (containing) a material with an antistatic/static inhibiting effect, such as a surfactant material or rubber material. In the display apparatus 1 of the exemplary embodiment, by subjecting the casing 21 to such anti-static treatment, attraction and adhesion of dirt or dust to the display section 2 can be reduced even if the display apparatus 1 is placed in a location covered in dirt or dust.

For example, sometimes static electricity is generated on the screen of the display apparatus 1 such as when power to the display apparatus 1 is switched on or off, or by friction. Dirt or dust is readily attracted or adhered to the surface when there is a state with a residual high electrical potential on the surface of the casing 21 due to static electricity generation, with the possibility of this reducing the aesthetics of the casing 21. If there is a residual high electrical potential in the vicinity of the display screen then there is also a possibility of light from the display screen being affected when the display screen becomes dirty. However, in the display apparatus 1 of the present exemplary embodiment, static electricity on the screen of the display apparatus 1 is suppressed by performing the anti-static treatment to the casing 21, and lowering of the aesthetics of the display apparatus 1 or degradation in the image quality of the display screen due to static electricity can be suppressed.

The casing 21 of the present exemplary embodiment is provided with both the front mask 21a and the back cover 21c. While generally static readily occurs at the periphery of a display screen with changes in electrical potential accompanying switching power on or off, dirt or dust can be suppressed from collecting or being attracted to the display screen or at the periphery of the display screen by subjecting the front mask 21 a in the exemplary embodiment to anti-static treatment. The aesthetics of the front face of the display apparatus 1 is important in a product display or as a piece of furniture decorating the interior of a room, and has the ability to ignite the purchasing interest of a consumer. In the present exemplary embodiment, the aesthetics of the display apparatus 1 when viewed from the front face can be maintained. Due to dirt not readily adhering a saving can also be made in the effort required by a user for cleaning.

As shown in FIG. 1, the speakers 111 are provided on the front mask 21a side. The speakers 111 are provided with undulating surfaces formed with holes or the like for efficient broadcasting of sound. While, for example, dirt or dust normally readily gets trapped in the undulating surfaces, due to performing anti-static treatment to the portion of the portion of the casing 21 configuring the speakers 111 in the display apparatus 1 of the exemplary embodiment, the aesthetics can be maintained at the periphery of the speakers 111 when viewed from the front face of the display apparatus 1. A saving in user effort for cleaning is also achieved.

As shown in FIG. 1, an LED 111a is provided at the front mask 21a face to show whether or not power is switched on. The LED 111a is, for example, regulated such that the amount of light emitted is not too strong in comparison to the amount of light from the display screen, in order not to have a detrimental impact on the light (image) from the display screen. However, were the anti-static treatment not to be performed, there would be a possibility that, as a result of dirt or dust accumulating and being deposited in the region surrounding the display screen, a layer of dirt is formed leading to a further reduction in the amount of light. However, in the display apparatus 1 of the present exemplary embodiment, reduction in the amount of light of the LED 111a can be suppressed due performing the anti-static treatment also to the portion of the casing 21 configuring the LED 111a.

In the present exemplary embodiment the back cover 21c is also subjected to anti-static treatment.

As shown in FIG. 3, protrusions and indentations are provided to the back cover 21c by configuring plural steps 113a, 113b. While, for example, dirt or dust might have been readily trapped in these protruding and indented portions, in the display apparatus 1 of the present exemplary embodiment, the aesthetics of the back cover 21c as viewed from the back face of the display apparatus 1 can be maintained due to also subjecting the portion of the casing 21 configuring the back cover 21 c to anti-static treatment.

Air outlet holes (not shown in the drawings) are, for example, provided in a top portion of the back cover 21c of the display apparatus 1 of the exemplary embodiment, and air intake holes (not shown in the drawings) are provided in the peripheral region 2bh of the back cover 21c. In the display apparatus 1 of the exemplary embodiment a fan 211 is housed in the casing 21. The fan 211 sucks in air from below the casing and expels air from the top side of the casing.

According to the display apparatus 1 of the present exemplary embodiment, the heat dissipation efficiency in the casing 21 can be raised by configuring a heat transfer path from the bottom to the top. Were the casing 21 not to have been subjected to anti-static treatment then air expelled from the air outlet holes 112 together with dirt or dust in the casing 21 would be emitted onto the external portion of the display apparatus 1 (at the top side of the display apparatus 1). Namely, there is a possibility that the dirt or dust from inside the casing 21 caught up in air expelled by the fan 211 would fall onto the top portion of the display apparatus 1 and be deposited there. However, the back cover 21c of the present exemplary embodiment is subjected to anti-static treatment, and so the aesthetics of the back cover 21c when viewed from the back face of the display apparatus 1 can be maintained.

Note that in the display apparatus 1 of the present exemplary embodiment the base section 3 and the connection portion 5 are also subjected to anti-static treatment. There is, in particular, a tendency to design the base section 3 with a wide surface area/support face in order to adequately support the display section 2, a heavy object. Deposits of dirt or dust are noticeable due to the large surface area either orthogonal or substantially orthogonal to the direction of gravity. However, in the present exemplary embodiment, the possibility of the base section 3 and the connection portion 5 becoming soiled due to dust particles can be reduced by a configuration in which the base section 3 and the connection portion 5 are subjected to anti-static treatment.

The display apparatus 1 of the present exemplary embodiment is configured from a synthetic resin material (plastic) into which is mixed (containing) a material with an antistatic/static inhibiting effect, such as a surfactant material or rubber material. However there is no limitation thereto and any configuration may be employed that can raise the surface resistivity of the display apparatus 1, for example, coating the surface of the screen of the display apparatus 1 with a coating material having an antistatic/static inhibiting effect is appropriate as anti-static treatment.

The surface resistivity of the casing 21 configuring the display apparatus 1 of the exemplary embodiment is, for example, set at about 1×1013 ohms/sq. According to the seidenki anzen shishin (static electricity safety guidelines) (1988 revision) published by the National Institute of Industrial Safety of the former Japanese Ministry of Labor, under standards for electrostatic insulators, a body having a surface resistivity value of 1×1010 ohms/sq or greater is an electrostatic insulator. The value of surface resistivity in the present exemplary embodiment falls within the above values.

An increase in the surface resistivity value of the casing 21 is achieved simply by using a large amount of antistatic material used. However, due to antistatic materials having low compatibility with synthetic resin materials currently used for forming casings 21, there is a tendency for antistatic materials to come to the surface when forming the casing 21. When this occurs traces of the flow of molten material during forming, called gate marks or flow marks, appear in the external appearance of the display apparatus 1. Namely, there is a possibility that well-defined gate marks or flow marks appear if attempts are made to raise the surface resistivity of the casing 21 simply be increasing the amount of antistatic material used, resulting in detriment to the aesthetics of the display apparatus 1.

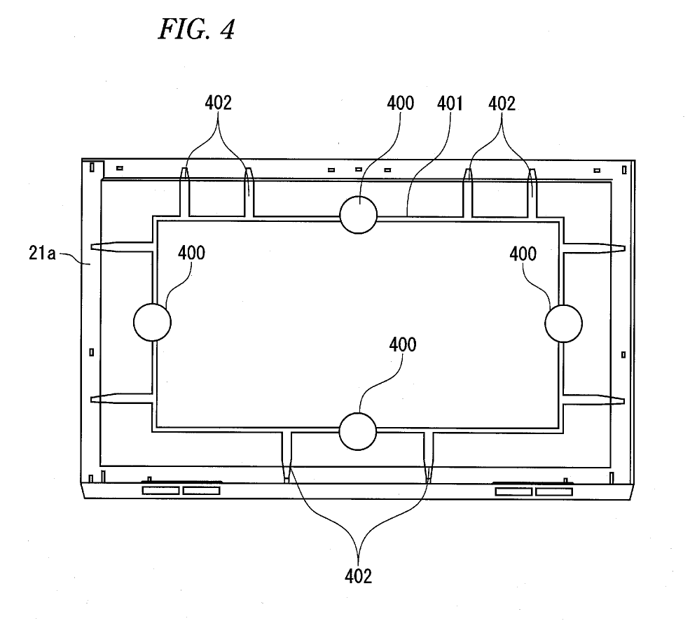

Accordingly, the casing 21 of the exemplary embodiment has a configuration which does not tend to leave gate marks or flow marks during molding. Explanation follows regarding the configuration of the casing 21 of the exemplary embodiment, with reference to FIG. 4 to FIG. 7.

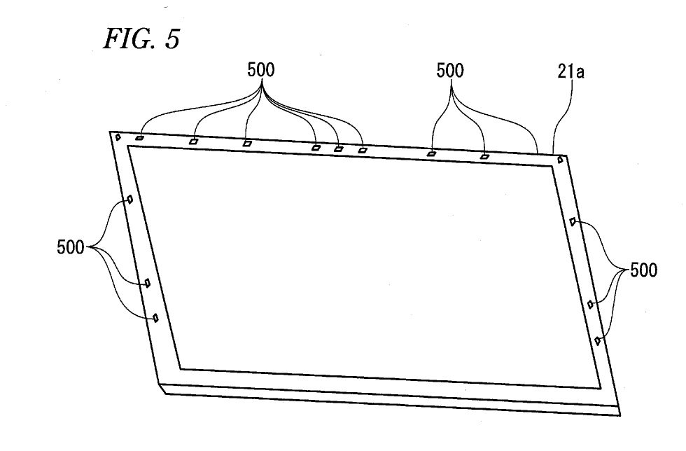

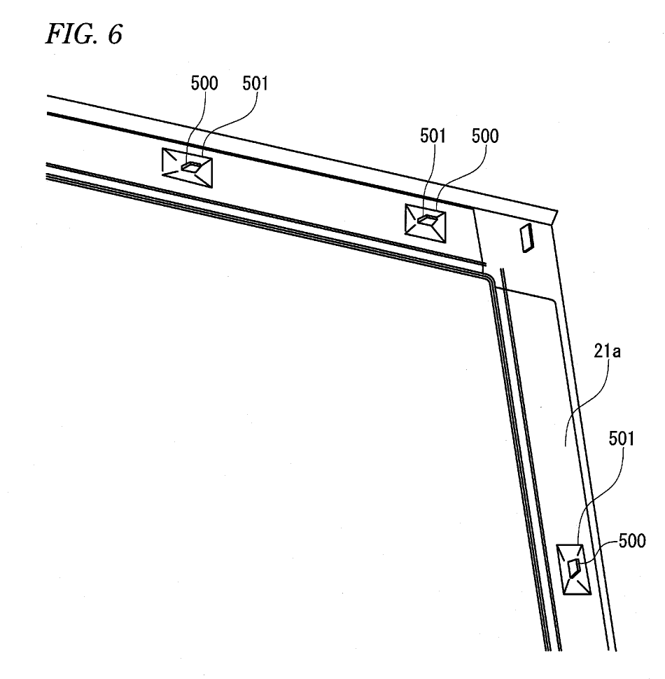

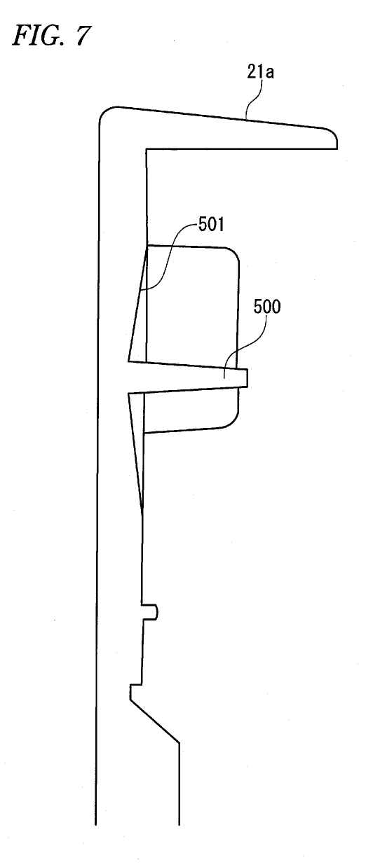

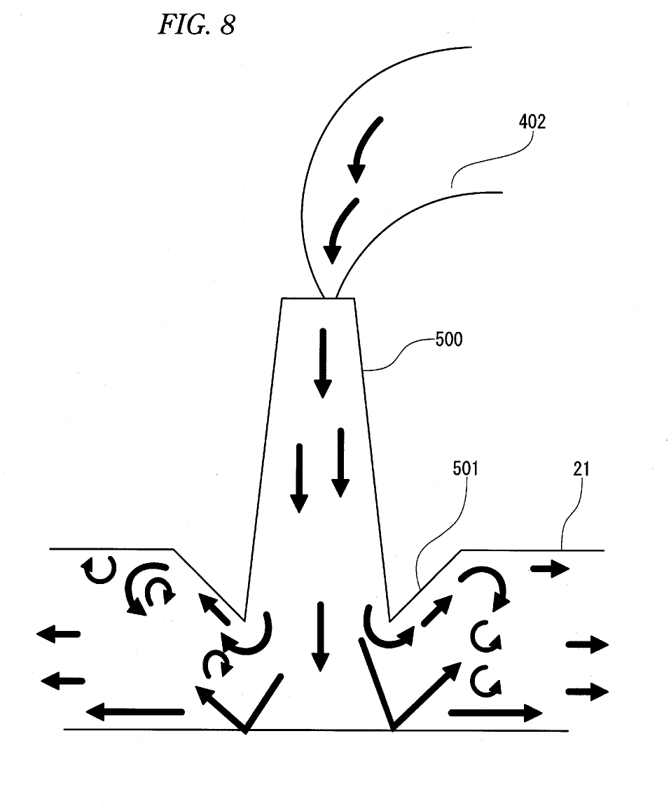

FIG. 4 shows a configuration of a casing of the exemplary embodiment during molding. FIG. 5 shows a front cover of an exemplary embodiment as viewed from the inside of the casing. FIG. 6 shows a partial enlargement of a state of the front cover as viewed from the inside of the casing. FIG. 7 shows an enlarged cross-section of a portion of the front cover of the present exemplary embodiment as viewed from the casing inside. FIG. 8 shows a schematic diagram of molten material flow in the present exemplary embodiment.

As shown in FIG. 4, when manufacturing the casing 21 a mold having specific indentation portions is fabricated and prepared, synthetic resin material for forming the casing 21 is then melted and injected into the mold. The static inhibiting material is either mixed in with the synthetic resin material at the time of injection, or has been mixed in previously.

As shown in FIG. 4, the molten material in the present exemplary embodiment is poured in via plural hot runners (poring portions, inlets) 400. The molten material spreads out through runners 401 and through the gates 402 into all the regions of the mold.

As shown in FIG. 5 and FIG. 7, the casing 21 of the present exemplary embodiment has connecting portions (projection portions, protrusions, connectors, tabs) 500 connected to the gates 402 and formed with shapes that project out from the peripheral wall of the casing 21. The projection portions 500 are positioned inside indentations (opening portions) 501 provided inside the casing 21.

Were the gates 402, for example, to be connected at positions in the same plane as the inside wall of the casing 21, then when the molten material is poured there would be a possibility of the antistatic material partially separating from the synthetic resin material, resulting in well-defined gate marks or flow marks appearing with detriment to the aesthetics of the display apparatus 1.

However, in the present exemplary embodiment, as shown in FIG. 5 to FIG. 8, configuration is made such that the gates 402 and the inner wall of the casing 21 are separated from each other. By adopting such a configuration, corner portions can be formed between the projection portions 500 and the inner wall of the casing 21, and turbulence can be achieved in a portion of the flow of the molten resin. Namely, by providing functionality to disturb the flow, for a portion of flow between the gates 402 and the inner wall of the casing 21, the probability of mixing of the antistatic material from a partially separated state into the synthetic resin material is raised.

For example, the indentations 501 in the present exemplary embodiment are the portions with the nearest separation distance to the opposite side (outside) of the casing 21, namely configure thinned portions to about half the average thickness of the casing 21. In such electronic devices following the recent trend towards thinner products, the strength of the casing 21 is weaker due to becoming extremely thin at the portions where the indentations 501 are provided. However, in the display apparatus of the present exemplary embodiment indentations 501 are designed to extend to the deepest indented portion within a range that does not affect the strength of the casing 21. In such an exemplary embodiment, restriction of the indentations 501 is set large (strong, deep) within a range that maintains the strength of the casing 21, thereby achieving a configuration in which disturbed flow can be more readily initiated.

The indentations 501 of the present exemplary embodiment are designed such that the depth of the region where the projection portions 500 and the casing 21 are connected, being the base of the projection portions 500, is the deepest location. Such a design enables a configuration to be achieved in which there is maximum restriction at the exit where the molten material flowing from the projection portions 500 to the casing 21 spreads out suddenly, better disturbing the flow of molten material. However, due to an effect already being achieved simply by providing the indentations 501 themselves, there is no limitation to the shape of the indentations 501 in the present exemplary embodiment and any configuration may be employed that achieves a restricting effect on the flow path cross-section.

The projection portions 500 are positioned in the vicinity of the edge (end) of the casing 21. After the molten material flowing into the mold has cooled and solidified the material is then ejected from the mold by pressing the ejector pins and the knockout frame. Generally in the vicinity at the center of the casing 21 there is no space for providing a projecting standing wall available and thus ejector pins are employed, and a knockout frame corresponding to the peripheral wall of the casing 21 is employed at the edge of the casing 21. Due to a knockout frame having a wider pressing surface (contact surface between the frame or pins and the casing 21) than ejector pins the casing 21 is not readily deformed at the periphery of the knockout frame. Namely, in the configuration of the present exemplary embodiment, by positioning the projection portions 500 in the vicinity of the edge (end) of the casing 21, the periphery of the projection portions 500 is not readily deformed during the separation operation from the mold, and gate marks or flow marks are suppressed from being noticeable.

As shown in FIG. 5 to FIG. 8, in the present exemplary embodiment, a configuration is adopted in which the projection portions 500 are provided at positions within the indentations 501 provided on the inner wall of the casing 21. Such a configuration results in the width of the flow path cross-section of flow of molten material out from the projection portions 500 being restricted. Namely, the flow path cross-section changes, and turbulence can be induced in a portion of the flow of the molten resin. Namely, similarly to configurations in which the gates 402 are distanced from the inner wall of the casing 21, due to providing capability to induce turbulence in a portion of the flow between the gates 402 and the casing 21, capability to mix the antistatic material from a partially separated state into the synthetic resin material is raised.

The surface of the display apparatus 1 of the present exemplary embodiment is provided with undulations, such as by a surface texturing process. Due to the display apparatus 1 of the exemplary embodiment having such a surface profile the obviousness can be reduced were any gate marks or flow marks to appear.

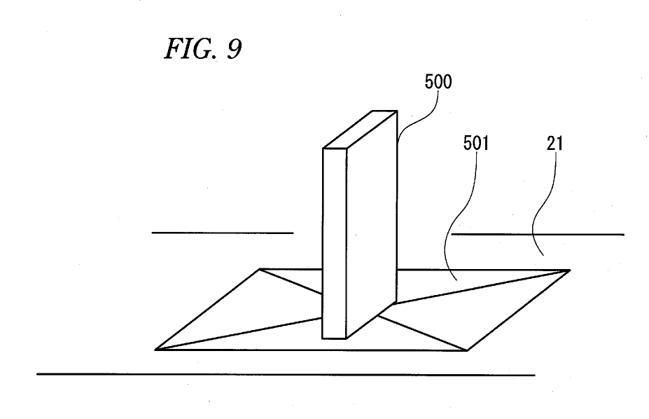

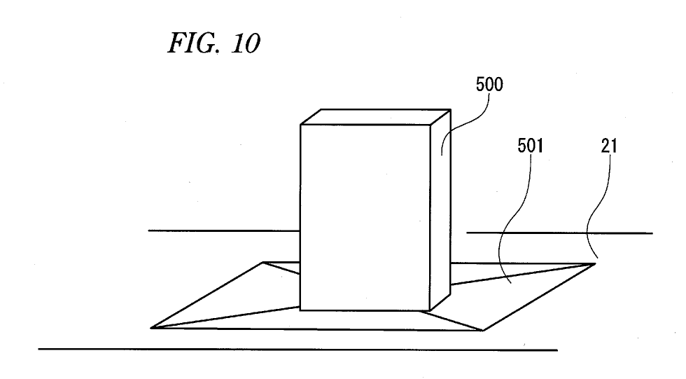

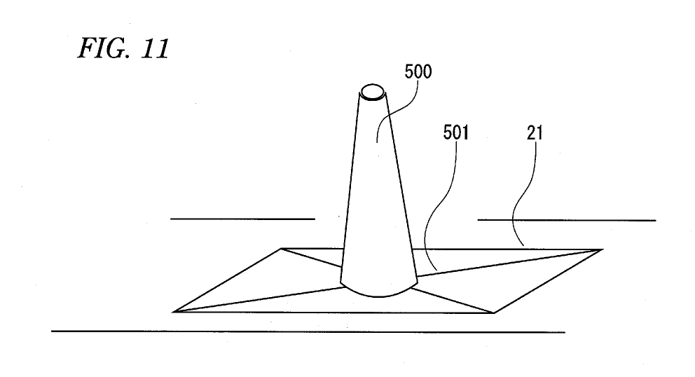

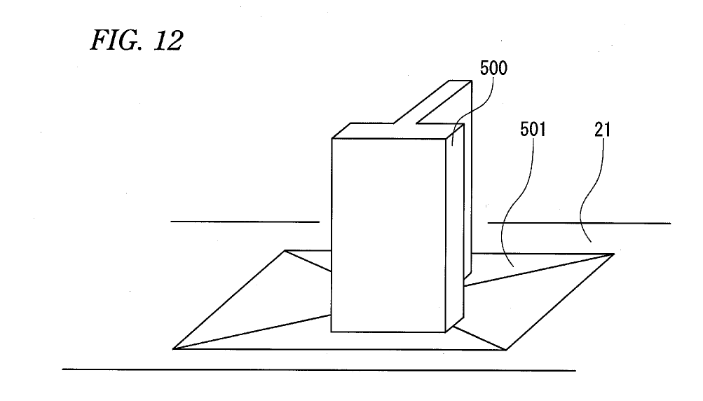

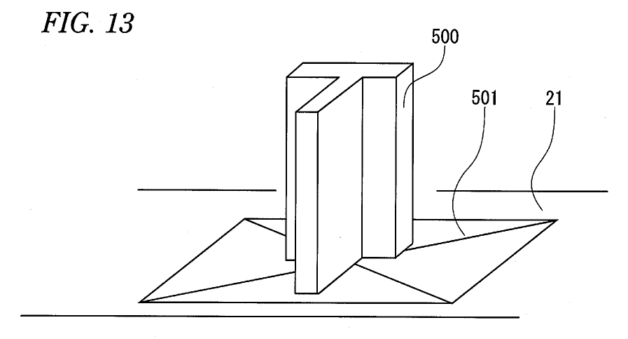

As long as the projection portions 500 are configured between the gates 402 and the inner wall of the casing 21 there is no limitation to the shapes shown in FIG. 5 to FIG. 8. Modified examples of the projection portions 500 are shown in FIG. 9 to FIG. 13. FIG. 9 is a first modified example of the projection portions of the present exemplary embodiment. FIG. 10 is a second modified example of the projection portions of the present exemplary embodiment. FIG. 11 is a third modified example of the projection portions of the present exemplary embodiment. FIG. 12 is a fourth modified example of the projection portions of the present exemplary embodiment. FIG. 13 is a fifth modified example of the projection portions of the present exemplary embodiment.

As shown in FIG. 9 and FIG. 10, turbulence can be more efficiently induced by changing the flow direction of the molten material, and changing the length direction of the projection portions according to the shape of the casing 21. For example, turbulence is more easily induced in the molten material when the length direction of the projection portions is set orthogonal to the flow direction compared to along the direction of flow. Similarly, when there is a certain width to the casing 21 at the periphery of the gates 402, turbulence is more readily induced when the length direction of the gates 402 is set orthogonal to the direction of flow of the molten material than when set along the direction of flow.

As shown in FIG. 11, changing the cross-section shape of the projection portions 500 by changing the width of the flow path results in a similar effect to configuration with the projection portions 500 positioned inside indented portions provided to the inner wall of the casing 21, namely restricting the width of the cross-section of the flow path. Changing the flow path cross-section enables a turbulence induction effect to be achieved to a portion of the flow of the molten resin.

As shown in FIG. 12 and FIG. 13, turbulence can be more readily induced inside the projection portions 500 by providing plural angular portions in the cross-sectional profile of the projection portions 500.

While explanation has been given of an electronic device according to exemplary embodiment there is no limitation to the above exemplary embodiments. Various configurations can be implemented by appropriate combinations of plural of the configuration elements described in the exemplary embodiments.

There is no limitation to a television for the electronic device to which the present exemplary embodiment is applied, and application is possible to various electronic devices, such as a digital camera and video camera, a personal digital assistant, a television, and a hard disk drive.

While certain embodiments have been described, these embodiments have been presented by way of example only, and are not intended to limit the scope of the invention. Indeed, the novel apparatus described herein may be embodied in a variety of other forms; furthermore, various omissions, substitutions and changes in the form of the apparatus, described herein may be made without departing from the sprit of the invention. The accompanying claims and their equivalents are intended to cover such forms or modifications as would fall within the scope and sprit of the invention.

What is claimed is:

1. A television comprising:
a display apparatus comprising a display screen;
a casing exhibiting a static inhibiting effect, the casing housing the display apparatus and comprising a first face section provided with an opening through which the display screen is exposed and a second face section positioned at the opposite side of the casing to the first face section;
a tuner housed in the casing; and
a support section exhibiting a static inhibiting effect and supporting the casing.

2. The television of claim 1, wherein the casing is configured including a synthetic resin material containing an antistatic material.

3. The television of claim 2, wherein the casing has a surface resistivity value of 1×1013 ohms/sq.

4. The television of claim 3, wherein the casing comprises a gate portion projecting out from an inside face of the casing.

5. The television of claim 4, wherein the gate portion is positioned inside an indented portion provided on the casing inside face.

6. The television of claim 4, wherein the gate portion is positioned at an edge of the first face section of the casing.

7. The television of claim 3, wherein a surface of the casing is subjected to surface texturing.

8. The television of claim 1, wherein a surface of the casing is coated with an antistatic material.

9. An electronic device comprising:
a display apparatus comprising a display screen; and
a casing exhibiting a static inhibiting effect, the casing housing the display apparatus, and comprising a first face section provided with an opening through which the display screen is exposed and a second face section positioned at the opposite side of the casing to the first face section.

10. An electronic device comprising:
a display apparatus comprising a display screen;
a casing housing the display apparatus; and
a support section exhibiting a static inhibiting effect and supporting the casing.
